(19) United States
(12) Patent Application Publication
(10) Pub. No.: US 2024/0387788 A1
(43) Pub. Date: Nov. 21, 2024

(54) HYBRID-DISPLAY

(71) Applicant: VueReal Inc., Waterloo (CA)

(72) Inventor: Gholamreza CHAJI, Waterloo (CA)

(73) Assignee: VueReal Inc., Waterloo, ON (CA)

(21) Appl. No.: 18/692,543

(22) PCT Filed: Sep. 15, 2022
(86) PCT No.: PCT/CA2022/051373

§ 371 Date: Mar. 15, 2024

Related U.S. Application Data
(60) Provisional application No. 63/244,330, filed on Sep. 15, 2021.

(51) Int. Cl. H01L 33/62; H01L 25/075; H01L 25/16; H01L 33/46

(52) U.S. Cl. CPC H01L 33/62; H01L 25/0753; H01L 25/167; H01L 33/46

(57) ABSTRACT

This invention is to use the light emitting devices with light modulations to eliminate the effect of bezels and match the pixels. It also enables the development of large displays. The invention discloses an array of light emitting devices along with light modulation devices housed with stage, backplane and pads. A filler with reflective material is also used within the housing.

### BACKGROUND AND FIELD OF THE INVENTION

The present disclosure relates generally to light emitting devices with light modulations.

### SUMMARY

The invention relates to an optoelectronic system comprising of arrays of light modulation devices and light emission devices, the system comprising, a light emitting device bonded to a backplane wherein a stage layer is formed around the light emitting device, the backplane having driving components for driving the light emitting device or the light modulation device, the light modulation device bonded to a top of a stage and the stage being a second layer of the backplane hosting an interconnect between the light modulation device, the driving components and backplane layers.

The invention relates to an optoelectronic system comprising of arrays of light modulation devices and light emission devices, the system comprising, a light emitting device and a light modulation device packaged on a first backplane, a first set pads formed on one side of the first backplane, the first set of pads being aligned with a second set of pads on the second backplane and bonded to the first backplane, a light modulation device installed on the first backplane and a stage separating the light modulation device from the light emitting device.

### BRIEF DESCRIPTION OF THE DRAWINGS

The foregoing and other advantages of the disclosure will become apparent upon reading the following detailed description and upon reference to the drawings.

FIG. 1A shows an optoelectronic system consisting of arrays of light modulation devices and light emission device

FIG. 1B shows another related embodiment where the reflective layer is made with some skeleton and inserted in the stage opening.

FIG. 1C shows a related embodiment where the light modulation has two substrates.

FIG. 2 shows a top view of the aforementioned optoelectronic system.

FIG. 3 shows a light emitting device 104 and light modulation device 106 are packaged on a separate backplane.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

The following description describes a method and a system to use light emitting devices with light modulations to eliminate the effect of bezels and match the pixels. Within the description a structure to execute the method or create a system is also described.

Emissive displays include backplane with pixels (or sub-pixels) and emissive devices that can generate lights for each pixel. The challenge of such displays is that the cost of the display will be very high due to using light emission devices for every pixel. Using smaller light emitting devices is one approach that limits the brightness and performance for some applications. The main advantage of discrete light emitting devices for display is that it enables larger displays.

This invention is to use the light emitting devices with light modulations to eliminate the effect of bezels and match the pixels. This also enables the development of large displays.

The light modulations can be liquid crystal, e-ink, or MEMS based shutters. The light emitting devices can be light emitting diodes, OLED, lasers, or other sources.

There is a backplane that has driving components for the light emitting devices and light modulation devices. The backplane can have places for arrays of light emitting devices and arrays of light modulation devices. The spacing between the light modulation devices can be optimized to be in the same range of the pixel pitch of the display.

The light modulation component formed with pads that can be bonded to the substrate. The pads are formed on one or more sides of the light modulation device. There are pads on the backplane associated with the light modulation device. Backplane also includes pads in the backplane for light emitting devices. There is a gap between the light emitting device and light modulation device. A stage can be formed in an area on the backplane associated with the edges

Z of the light modulation device to create the said gap. The stage can be another backplane bonded to the first backplane. In another case, the stage can be formed by polymers, conductive layers or other forms. The pads associated with the light modulation device are formed on top of the stage. There are conductive traces coupling the pads on the stage to the backplane. The stage can develop a housing around the light emitting device. There can be reflective layers covering at least part of the housing sides for directing the light from the light emitting device to the light modulation devices. In other related cases, the reflective layers can be extended to over the pad height. The housing can be at least partially filled with optical enhancement layers or materials. One of these materials can be color conversion, light distribution layers and so on. There can be different light emitting devices generating light in different wavelength ranges (e.g., green, red, Blue).

The light modulation can have different sub pixels with color filters or color conversion layers for each subpixels. In a related embodiment, the light modulation device has two sets of pixels, reflective and transmissive pixels. Reflective pixels have color filters transmissive pixels can have or not have color filters (or color conversion layers). When the ambient light is higher than the light of the light emitting device, the light emitting device can be turned off and only reflective pixels show content. If the ambient light is below a threshold, the reflective pixels are turned off and only the transmissive pixels are turned on.

If the pixels do not have color filters (or color conversion layers), the light emitting device cycles through different colors in sync with the light modulation device during each frame creating sub frames with different colors. In one related embodiment, each adjacent light modulation device in a backplane shows a different color during each subframe to enhance viewing experience.

The light modulation can have only one subpixels allowing different lights with different wavelength ranges pass through it. The sub pixels are developed by time modulations.

The ambient light can be passed through the light modulator and reflected back by the reflection layers. If the polarity of light is important for the light modulator, layers can be added between reflector and light modulator to either change the light modulation or randomize it.

If the light modulation has two substrates (the first substrate with pixel circuits and contact pads and the second substrate with no contact pads). The second substrate with no pads can be smaller than the first substrate with pads to provide access for pads. The second substrate can be smaller than the housing and so part of the second substrate can fit inside the housing.

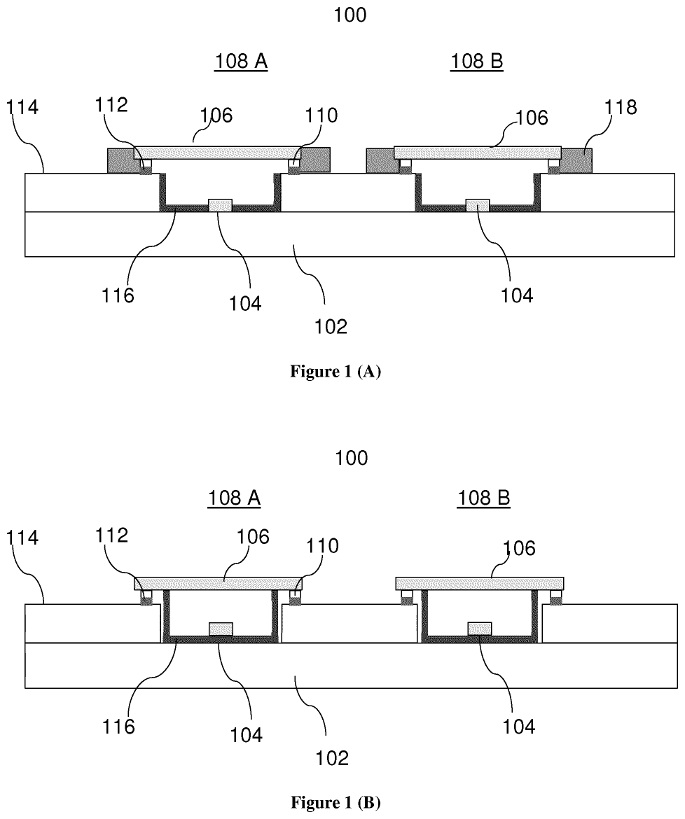

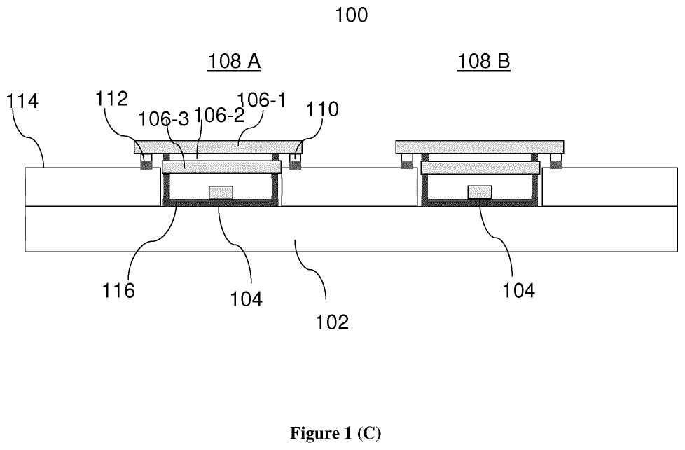

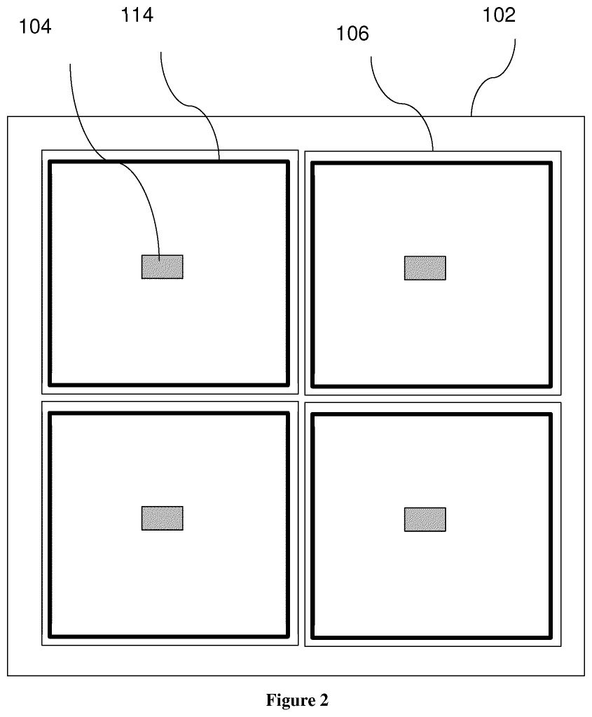

FIG. 1A shows an optoelectronic system 100 comprising arrays of light modulation devices 106 (in packaged devices 108A and 108B) and light emission devices 104. In one related embodiment, the light emitting device 104 is bonded to a backplane 102 where a stage layer 114 is formed around the light emitting device 104. The backplane can have driving components for driving the light emitting device 104 or the light modulation device 106. The light modulation device 106 is bonded to the top of the stage 114. The stage 114 can be a second layer of the backplane hosting interconnect between light modulation device 106, driving components or backplane layers. Also, the stage layer can have driving components. The stage layer can have pads 112 that are coupled to the pads 110 in light modulation device 106. The pads can be metal, solder, or other materials. At least part of the stage wall or covered with reflective materials 116. Here the reflective materials can be as foil laminated to the walls and surface or deposited on the surface. After bonding the light modulation 106 to the stage 114, filler material 118 can be used to cover the edge of the light modulation to eliminate any light leakage. The filler material 118 can fill all the space between the light modulation devices 106.

FIG. 1B shows another related embodiment where the reflective layer 116 is made with some skeleton and inserted in the stage opening. In one related embodiment, the reflective structure 116 is extended to the light modulation device 106.

C

FIG. 1C shows a related embodiment where the light modulation has two substrates 106-1 and 106-3. Here there can be a cavity 106-2 between the two substrates. There can be other layers included in the substrates 106-1 and 106-3. Here, the first substrate 106-1 can include the electrical modulation component and circuits and the contact pads. The second backplane 106-3 can be as passivation or include other components. The two substrates can be encapsulated from the edge. The second backplane is smaller than the first substrate 106-1. It also can be smaller than the opening created by stage 114. Here the second substrate 106-3 fits partially or fully in the opening created by the stage 114.

FIG. 2 shows a top view of the aforementioned optoelectronic system. Here stage 114 is formed on the backplane 102 and creates an opening where the light emitting device 104 is residing. The light modulation element 106 is aligned and bonded to the stage 114.

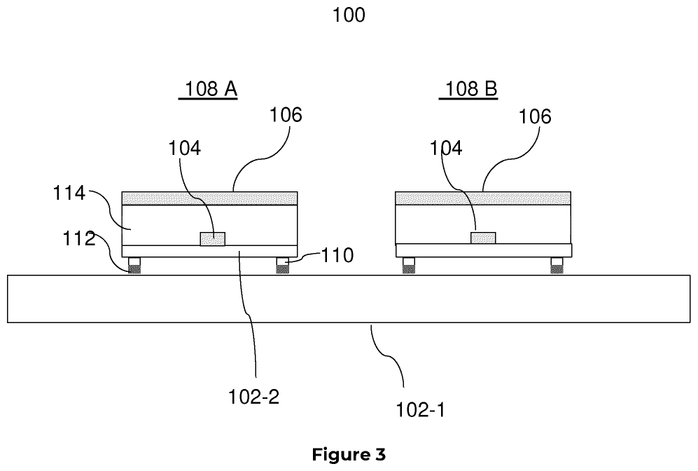

In another related embodiment, as shown in FIG. 3, a light emitting device 104 and light modulation device 106 are packaged on a separate backplane 102-2. Pads 110 are formed on one side of backplane 102-2. The pads 110 are aligned with the pads 112 on the first backplane 102-1 and bonded to the first backplane 102-1. The light modulation 106 can be installed on the second backplane 102-2 via stage 114 similar to the embodiment discussed in FIG. 1 where stage is used to separate the light modulation device from the light emitting device. The space between the packaged devices 108A and 108B can be filled with a filler layer. The filler layer can be black matrix or a reflective layer. An array of the packaged backplane 102-2 can be used to connect to the first backplane 102-1 to create a larger display array.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. An optoelectronic system comprising of arrays of light modulation devices and light emission devices, the system comprising:
a light emitting device bonded to a backplane wherein a stage layer is formed around a light emitting device;
the backplane having driving components for driving the light emitting device or a light modulation device;
the light modulation device bonded to a top of a stage; and
the stage being a second layer of the backplane hosting an interconnect between the light modulation device, the driving components or backplane layers.

2. The system of claim 1, wherein the stage layer has driving components.

3. The system of claim 1, wherein the stage layer has pads coupled to pads in light modulation device.

4. The system of claim 3, wherein the pads are metal, or solder.

5. The system of claim 1, wherein at least part of a stage wall is covered with reflective materials

6. The system of claim 5, wherein the reflective materials are as a foil laminated to walls and a surface or deposited on the surface.

7. The system of claim 1, wherein a filler material covers the edge of the light modulation.

8. The system of claim 7, wherein the filler material fills the space between light modulation devices.

9. The system of claim 5, wherein a reflective layer is made with a skeleton and inserted in a stage opening.

10. The system of claim 9, wherein the reflective layer is extended to the light modulation device.

11. The system of claim 10, wherein the light modulation has two backplanes encapsulated from the edge with a cavity between the two backplanes.

12. The system of claim 11, a first backplane includes an electrical modulation component, circuits and contact pads and a second backplane is a passivation.

13. The system of claim 11, wherein the second backplane is smaller than the first backplane.

14. The system of claim 11, wherein the second backplane is smaller than than an opening created by the stage.

15. The system of claim 12, wherein the second backplane fits partially or fully in an opening created by the stage.

16. The system of claim 1, wherein the light modulation device is aligned to the stage.

17. An optoelectronic system comprising of arrays of light modulation devices and light emission devices, the system comprising:
a light emitting device and a light modulation device packaged on a first backplane;
a first set pads formed on one side of the first backplane;
the first set of pads being aligned with a second set of pads on the second backplane and bonded to the first backplane;
a light modulation device installed on the first backplane; and
a stage separating the light modulation device from the light emitting device.

18. The system of claim 17, wherein a space between the packaged devices is filled with a filler layer.

19. The system of claim 18 wherein the filler is a black matrix.

20. The system of claim 17, wherein an array of the first backplane is connected to the second backplane.
